(19) United States
(12) Patent Application Publication
(10) Pub. No.: US 2022/0341039 A1
(43) Pub. Date: Oct. 27, 2022

(54) RUTHENIUM PYRAZOLATE PRECURSOR FOR ATOMIC LAYER DEPOSITION AND SIMILAR PROCESSES

(71) Applicant: Merck Patent GmbH, Darmstadt (DE)

(72) Inventors: Guo LIU, Haverhill, MA (US); Jean-Sébastien M. LEHN, Winchester, MA (US); Charles DEZELAH, Helinki (FI); Jacob WOODRUFF, Lexington, MA (US); Jason P. COYLE, Ontario (CA)

(21) Appl. No.: 17/764,292

(22) PCT Filed: Nov. 24, 2020
(86) PCT No.: PCT/EP2020/083152

§ 371 Date: Mar. 28, 2022

Related U.S. Application Data
(60) Provisional application No. 62/940,524, filed on Nov. 26, 2019.

(51) Int. Cl. C23C 16/455; C23C 16/18

(52) U.S. Cl. CPC C23C 16/45527; C23C 16/18

(57) ABSTRACT

The disclosed and claimed subject matter relates to the ruthenium pyrazolate precursors and derivatives thereof as well as their uses in ALD or ALD-like processes and the films grown is such processes. In particular substituted unsaturated pyrazolate bridged diruthenium carbonyl complexes are disclosed.

### BACKGROUND

### Field

The disclosed and claimed subject matter relates to metal-containing precursors for use in atomic layer deposition (ALD) and ALD-like processes for selective metal-containing film growth on at least one substrate. In particular, the disclosed and claimed subject matter relates to a ruthenium pyrazolate precursor and derivatives thereof that are useful in ALD and ALD-like processes.

### Related Art

Thin films, and in particular, thin metal-containing films, have a variety of important applications, such as in nanotechnology and the fabrication of semiconductor devices. Examples of such applications include high-refractive index optical coatings, corrosion-protection coatings, photocatalytic self-cleaning glass coatings, biocompatible coatings, dielectric capacitor layers and gate dielectric insulating films in field-effect transistors (FETs), capacitor electrodes, gate electrodes, adhesive diffusion barriers, and integrated circuits. Metallic thin films and dielectric thin films are also used in microelectronics applications, such as the high-κ dielectric oxide for dynamic random-access memory (DRAM) applications and the ferroelectric perovskites used in infrared detectors and non-volatile ferroelectric random-access memories (NV-FeRAMs).

Various precursors may be used to form metal-containing thin films and a variety of deposition techniques can be employed. Such techniques include reactive sputtering, ion-assisted deposition, sol-gel deposition, chemical vapor deposition (CVD) (also known as metalorganic CVD or MOCVD), and atomic layer deposition (ALD) (also known as atomic layer epitaxy). CVD and ALD processes are increasingly used as they have the advantages of enhanced compositional control, high film uniformity, and effective control of doping.

Conventional CVD is a chemical process whereby precursors are used to form a thin film on a substrate surface. In a typical CVD process, the precursors are passed over the surface of a substrate (e.g., a wafer) in a low pressure or ambient pressure reaction chamber. The precursors react and/or decompose on the substrate surface creating a thin film of deposited material. Volatile by-products are removed by gas flow through the reaction chamber. The deposited film thickness can be difficult to control because it depends on coordination of many parameters such as temperature, pressure, gas flow volumes and uniformity, chemical depletion effects, and time.

ALD is also a method for the deposition of thin films. It is a self-limiting, sequential, unique film growth technique based on surface reactions that can provide precise thickness control and deposit conformal thin films of materials provided by precursors onto surfaces substrates of varying compositions. In ALD, the precursors are separated during the reaction. The first precursor is passed over the substrate surface producing a monolayer on the substrate surface. Any excess unreacted precursor is pumped out of the reaction chamber. A second precursor is then passed over the substrate surface and reacts with the first precursor, forming a second monolayer of film over the first-formed monolayer of film on the substrate surface. This cycle is repeated to create a film of desired thickness.

For conventional chemical vapor deposition (CVD) process, the precursor and co-reactant are introduced into a deposition chamber via vapor phase to deposit a thick film on the substrate. On other hand, atomic layer deposition (ALD) or ALD-like process, the precursor and co-reactant are introduced into a deposition chamber sequentially, thus allowing a surface-controlled layer-by-layer deposition and importantly self-limiting surface reactions to achieve atomic-level growth of thin film. The key to a successful ALD deposition process is to employ a precursor to devise a reaction scheme consisting of a sequence of discrete, self-limiting adsorption and reaction steps. One great advantage of the ALD process is to provide much higher conformality for substrates having high aspect ratio such as >8 than CVD.

However, the continual decrease in the size of microelectronic components, such as semi-conductor devices, presents several technical challenges and has increased the need for improved thin film technologies. In particular, microelectronic components may include features on or in a substrate, which require filling, e.g., to form a conductive pathway or to form interconnections. Filling such features, especially in smaller and smaller microelectronic components, can be challenging because the features can become increasingly thin or narrow. Consequently, a complete filling of the feature, e.g., via ALD, would require infinitely long cycle times as the thickness of the feature approaches zero. Moreover, once the thickness of the feature becomes narrower than the size of a molecule of a precursor, the feature cannot be completely filled. As a result, a hollow seam can remain in a middle portion of the feature when ALD is performed. The presence of such hollow seams within a feature is undesirable because they can lead to failure of the device. Accordingly, there exists significant interest in the development of thin film deposition methods, particularly ALD methods that can selectively grow a film on one or more substrates and achieve improved filling of a feature on or in a substrate, including depositing a metal-containing film in a manner which substantially fills a feature without any voids.

Some ruthenium pyrazolate precursors have been described and used in conventional CVD processes in the high temperature range of 300-450° C. See, e.g., Song, Yi-Hwa, et al., “A Study of Unsaturated Pyrazolate-Bridged Diruthenium Carbonyl Complexes,” Organometallics 2002, 21, p. 4735-4742 and Song, Yi-Hwa, et al., “Deposition of Conductive Ru and RuO₂ Thin Films Employing a Pyrazolate Complex [Ru(CO)₃(3,5-(CF₃)₂-pz)]₂ as the CVD Source Reagent,” Chemical Vapor Deposition, 2003, V9 (3), p. 162-169. However, their use in ALD and ALD-like (e.g., cyclic CVD) at lower temperatures below 300° C. has not been shown until now.

### SUMMARY

In one aspect, the disclosed and claimed subject matter relates to ruthenium pyrazolate precursors of Formula I:

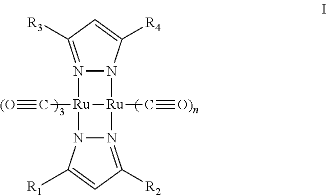

where R₁, R₂, R₃ and R₄ are each independently selected from the group of a substituted or unsubstituted C₁ to C₂₀ linear or branched or cyclic alkyl and a substituted or unsubstituted C₁ to C₂₀ linear or branched or cyclic halogenated alkyl and where n=2 or 3. In another aspect of this embodiment, R₁, R₂, R₃ and R₄ are each independently one of —CH₃, —CH₂CH₃, CH₂CH₂CH₃, CH(CH₃)₂, —CH₂CH(CH₃)₂ and —C(CH₃)₃. The Ru-Pz precursor is a member of the class of compounds covered by Formula I. In another aspect of this embodiment, one or more of R₁ R₂, R₃ and R₄ is sterically bulky group (e.g., t-butyl groups). In another aspect of this embodiment, one or more of R₁ R₂, R₃ and R₄ is each independently one of CF₃, —CF₂CF₃, —CF₂CF₂CF₃, —CF(CF₃)₂, —C(CF₃)₃, and any substituted or unsubstituted C₁ to C₈ perfluorinated alkyl. In another aspect of this embodiment, each of R₁ and R₄ are the same group. In another aspect of this embodiment, each of R₂ and R₃ are the same group. In another aspect of this embodiment, each of R₁, R₂, R₃ and R₄ is the same group. In one aspect of this embodiment, n=2. In one aspect of this embodiment, n=3.

In another aspect, the disclosed and claimed subject matter relates to the use of precursors having Formula I in ALD and ALD-like processes. In a further aspect of this embodiment, the ALD or ALD-like process comprises the step of depositing a ruthenium-containing layer derived from a precursor of Formula I on a surface of a substrate. In a further aspect of this embodiment, the ALD or ALD-like processes using precursors having Formula I are applied to grow a film on a substrate including one or more of Al₂O₃, ZrO₂, HfO₂ and SiO₂, a non-oxide such as WCN, WN and TiN, or a metal surface such as Cu, Co, Mo or W. In a further aspect of this embodiment, the process comprises the use of a co-reactant.

In another aspect the disclosed and claimed subject matter relates to films grown from precursors having Formula I. In a further aspect of this embodiment, the films are grown on a substrate including one or more of Al₂O₃, ZrO₂, HfO₂ and SiO₂, a non-oxide such as WCN, WN and TiN, or a metal surface such as Cu, Co, Mo or W.

In one aspect, the disclosed and claimed subject matter relates to a ruthenium pyrazolate precursor having the following structure:

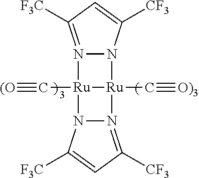

(herein “Ru-Pz 1”) as well as derivatives thereof for use in ALD or ALD-like processes. In a further aspect of this embodiment, the ALD or ALD-like process is applied to grow a film on a substrate including one or more of an oxide substrate or surface such as Al₂O₃, ZrO₂, HfO₂ and SiO₂, a non-oxide such as WCN, WN and TiN, or a metal surface such as Cu, Co, Mo or W. In a further aspect of this embodiment, the ALD or ALD-like process is conducted at a temperature below approximately 300° C. In a further aspect of this embodiment, the ALD or ALD-like process is conducted at a temperature below approximately 275° C. In a further aspect of this embodiment, the ALD or ALD-like process is conducted at a temperature below approximately 250° C. In a further aspect of this embodiment, the ALD or ALD-like process is conducted at a temperature in the range of approximately 200° C. and approximately 300° C. In a further aspect of this embodiment, the ALD or ALD-like process is conducted at a temperature in the range of approximately 235° C. and approximately 300° C.

Among other things, the Ru-Pz 1 precursor (i) is solid at room temperature, (ii) is thermally stable, (iii) has a vapor pressure sufficient to enable evaporation at standard operating temperatures and pressures and (iv) can be utilized to deposit Ru films with a resistivity of as low as approximately 20μΩ-cm at approximately 275° C. (as-deposited).

In one aspect, the disclosed and claimed subject matter relates to a ruthenium pyrazolate precursor having the following structure:

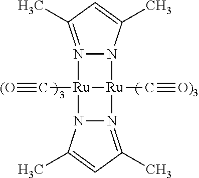

(herein “Ru-Pz 2”) as well as derivatives thereof for use in ALD or ALD-like processes. In a further aspect of this embodiment, the ALD or ALD-like process is applied to grow a film on a substrate including one or more of an oxide substrate or surface such as Al₂O₃, ZrO₂, HfO₂ and SiO₂, a non-oxide such as WCN, WN and TiN, or a metal surface such as Cu, Co, Mo or W. In a further aspect of this embodiment, the ALD or ALD-like process is conducted at a temperature below approximately 300° C. In a further aspect of this embodiment, the ALD or ALD-like process is conducted at a temperature below approximately 275° C. In a further aspect of this embodiment, the ALD or ALD-like process is conducted at a temperature below approximately 250° C. In a further aspect of this embodiment, the ALD or ALD-like process is conducted at a temperature in the range of approximately 200° C. and approximately 300° C. In a further aspect of this embodiment, the ALD or ALD-like process is conducted at a temperature in the range of approximately 235° C. and approximately 300° C.

In one aspect, the disclosed and claimed subject matter relates to a ruthenium pyrazolate precursor having the following structure:

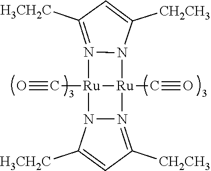

(herein “Ru-Pz 3”) as well as derivatives thereof for use in ALD or ALD-like processes. In a further aspect of this embodiment, the ALD or ALD-like process is applied to grow a film on a substrate including one or more of an oxide substrate or surface such as Al₂O₃, ZrO₂, HfO₂ and SiO₂, a non-oxide such as WCN, WN and TiN, or a metal surface such as Cu, Co, Mo or W. In a further aspect of this embodiment, the ALD or ALD-like process is conducted at a temperature below approximately 300° C. In a further aspect of this embodiment, the ALD or ALD-like process is conducted at a temperature below approximately 275° C. In a further aspect of this embodiment, the ALD or ALD-like process is conducted at a temperature below approximately 250° C. In a further aspect of this embodiment, the ALD or ALD-like process is conducted at a temperature in the range of approximately 200° C. and approximately 300° C. In a further aspect of this embodiment, the ALD or ALD-like process is conducted at a temperature in the range of approximately 235° C. and approximately 300° C.

In another aspect, the disclosed and claimed subject matter relates to a ruthenium pyrazolate precursor having the following structure:

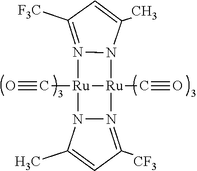

(herein “Ru-Pz 4”) as well as derivatives thereof for use in ALD or ALD-like processes. In a further aspect of this embodiment, the ALD or ALD-like process is applied to grow a film on a substrate including one or more of an oxide substrate or surface such as Al₂O₃, ZrO₂, HfO₂ and SiO₂, a non-oxide such as WCN, WN and TiN, or a metal surface such as Cu, Co, Mo or W. In a further aspect of this embodiment, the ALD or ALD-like process is conducted at a temperature below approximately 300° C. In a further aspect of this embodiment, the ALD or ALD-like process is conducted at a temperature below approximately 275° C. In a further aspect of this embodiment, the ALD or ALD-like process is conducted at a temperature below approximately 250° C. In a further aspect of this embodiment, the or ALD-like ALD process is conducted at a temperature in the range of approximately 200° C. and approximately 300° C. In a further aspect of this embodiment, the ALD or ALD-like process is conducted at a temperature in the range of approximately 235° C. and approximately 300° C.

In another aspect, the disclosed and claimed subject matter relates to a ruthenium pyrazolate precursor having the following structure:

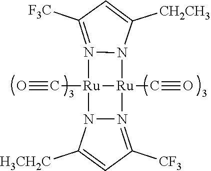

(herein “Ru-Pz 5”) as well as derivatives thereof for use in ALD or ALD-like processes. In a further aspect of this embodiment, the ALD or ALD-like process is applied to grow a film on a substrate including one or more of an oxide substrate or surface such as Al₂O₃, ZrO₂, HfO₂ and SiO₂, a non-oxide such as WCN, WN and TiN, or a metal surface such as Cu, Co, Mo or W. In a further aspect of this embodiment, the ALD or ALD-like process is conducted at a temperature below approximately 300° C. In a further aspect of this embodiment, the ALD or ALD-like process is conducted at a temperature below approximately 275° C. In a further aspect of this embodiment, the ALD or ALD-like process is conducted at a temperature below approximately 250° C. In a further aspect of this embodiment, the ALD or ALD-like process is conducted at a temperature in the range of approximately 200° C. and approximately 300° C. In a further aspect of this embodiment, the ALD or ALD-like process is conducted at a temperature in the range of approximately 235° C. and approximately 300° C.

In another aspect the disclosed and claimed subject matter relates to films grown from the Ru-Pz precursors and derivatives thereof. In a further aspect of this embodiment, the films are grown on an oxide substrate or surface such as Al₂O₃, ZrO₂, HfO₂ and SiO₂, a non-oxide such as WCN, WN and TiN, or a metal surface such as Cu, Co, Mo or W.

In one aspect, the disclosed and claimed subject matter relates to Ru-containing films grown by ALD or ALD-like processes using the Ru-Pz precursors in alternating pulses with a carrier gas (e.g., H₂). Such films grown at 255° C. exhibit low resistivity. Such films can be thin (ca. 10-150 Å) or thicker. Thinner films on the order of approximately 150 Å exhibit a resistivity of around 20 μOhm·cm.

In another aspect, the disclosed and claimed subject matter relates to the use of the Ru-Pz precursors in ALD or ALD-like processes.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates the TGA/DSC analysis of the Ru-Pz 1, Ru-Pz 2, Ru-Pz 3 precursors showing stability and volatility;

FIG. 2 illustrates the Ru growth rate and resistivity versus Ru-Pz 1 ampule temperature and vapor pressure;

FIG. 3 illustrates the growth rate and resistivity versus reactor pressure;

FIG. 4 illustrates Ru resistivity and growth/cycle as a function of deposition temperature for Ru films grown from the Ru-Pz 1 precursor;

FIG. 5 illustrates the homogeneity (over an 8-inch crossflow deposition chamber) of Ru films grown from the Ru-Pz 1 precursor when deposited at 255-275° C.;

FIG. 6 illustrates thickness and growth/cycle at 245° C. as a function of number of cycles of Ru films grown from the Ru-Pz 1 precursor;

FIG. 7 illustrates resistivity as a function of film thickness of Ru films grown from the Ru-Pz 1 precursor;

FIG. 8 illustrates the effect of purge length on growth of Ru films grown from the Ru-Pz 1 precursor at 245° C.;

FIG. 9 illustrates an XPS analysis of thick Ru film grown from the Ru-Pz 1 precursor deposited on native SiO₂;

FIG. 10 illustrates an XPS analysis of thin Ru film grown from the Ru-Pz 1 precursor deposited on Al₂O₃;

FIG. 11 illustrates film morphology at 275° C. (200 cycles) on Al₂O₃, SiO₂ and TiN surfaces;

FIG. 12 illustrates conformality of an Ru film grown (400 cycles of alternating Ru-Pz and H₂ at 275° C.) from the Ru-Pz 1 precursor on vias with a 20:1 aspect ratio;

FIG. 13 illustrates conformality of an Ru film grown (400 cycles of alternating Ru-Pz and H₂ at 275° C.) from the Ru-Pz precursor on vias with a 20:1 aspect ratio, higher magnification micrographs centered on via top and via bottom;

FIG. 14 illustrates the deposition of a Ru film grown from the Ru-Pz 1 precursor in the absence of H₂ (275° C.) in a crossflow reactor;

FIG. 15 illustrates RBS data showing that at 2.024 MeV only the Ru and Si elements can be quantified above the detection limit (filled symbols are collected data and solid lines are fits to RBS spectra with SIMNRA software);

FIG. 16 illustrates RBS data showing that at 3.043 MeV only the Ru and Si elements can be quantified above the detection limit (filled symbols are collected data, and solid lines are fits to RBS spectra with SIMNRA software);

FIG. 17 illustrates RBS data showing that at 4.282 MeV only the Ru and Si elements can be quantified above the detection limit (filled symbols are collected data, and solid lines are fits to RBS spectra with SIMNRA software);

FIG. 18 illustrates RBS data showing that carbon is non-detectable in a Ru film grown from the Ru-Pz precursor with H₂ (275° C.) in a crossflow reactor and how simulated levels of carbon would be measured to quantify the detection limit;

FIG. 19 illustrates RBS data showing that oxygen is non-detectable in a Ru film grown from the Ru-Pz precursor with H₂ (275° C.) in a crossflow reactor and how simulated levels of oxygen would be measured to quantify the detection limit;

FIG. 20 illustrates the conclusion of the RBS analysis in which an Ru film having 255 monolayers of Ru on the Si substrate and topped with 22 monolayers of “C_{0.5}H_{0.5}” due to surface contamination by ambient air; and

FIG. 21 illustrates an XRD showing an Ru phase.

### DEFINITIONS

Unless otherwise stated, the following terms used in the specification and claims shall have the following meanings for this application.

For purposes of this invention and the claims hereto, the numbering scheme for the Periodic Table Groups is according to the IUPAC Periodic Table of Elements.

The term “and/or” as used in a phrase such as “A and/or B” herein is intended to include “A and B,” “A or B,” “A” and “B.”

The terms “substituent,” “radical,” “group” and “moiety” may be used interchangeably.

As used herein, the terms “metal-containing complex” (or more simply, “complex”) and “precursor” are used interchangeably and refer to metal-containing molecule or compound which can be used to prepare a metal-containing film by a vapor deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal oxide film, metal nitride film, metal silicide film, a metal carbide film and the like. As used herein, the terms “elemental metal film” and “pure metal film” are used interchangeably and refer to a film which consists of, or consists essentially of, pure metal. For example, the elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. Unless context dictates otherwise, the term “metal film” shall be interpreted to mean an elemental metal film.

As used herein, the term “vapor deposition process” is used to refer to any type of vapor deposition technique, including but not limited to, CVD and ALD. In various embodiments, CVD may take the form of conventional (i.e., continuous flow) CVD, liquid injection CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al. J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds., The Royal Society of Chemistry: Cambridge, 2009; Chapter 1, pp 1-36.

Throughout the description, the terms “ALD or ALD-like” or “ALD and ALD-like” refer to a process including, but is not limited to, the following processes: (i) sequentially introducing each reactant, including the Ru-Pz precursors and a reactive gas, into a reactor such as a single wafer ALD reactor, semi-batch ALD reactor, or batch furnace ALD reactor; (ii) exposing a substrate to each reactant, including the Ru-Pz precursors and the reactive gas, by moving or rotating the substrate to different sections of the reactor where each section is separated by inert gas curtain, i.e., spatial ALD reactor or roll to roll ALD reactor. A typical cycle of an ALD or ALD-like process includes at least four steps as aforementioned.

As used herein, the term “feature” refers to an opening in a substrate which may be defined by one or more sidewalls, a bottom surface, and upper corners. In various aspects, the feature may be a via, a trench, contact, dual damascene, etc.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

The disclosed and claimed precursors are preferably substantially free of water. As used herein, the term “substantially free” as it relates to water, means less than 5000 ppm (by weight) measured by proton NMR or Karl Fischer titration, preferably less than 3000 ppm measured by proton NMR or Karl Fischer titration, and more preferably less than 1000 ppm measured by proton NMR or Karl Fischer titration, and most preferably 100 ppm measured by proton NMR or Karl Fischer titration.

The disclosed and claimed precursors are also preferably substantially free of metal ions or metals such as, Li⁺ (Li), Na⁺ (Na), K⁺ (K), Mg²⁺ (Mg), Ca²⁺ (Ca), Al³⁺ (Al), Fe²⁺ (Fe), Fe³⁺ (Fe), Ni²⁺ (Fe), Cr³⁺ (Cr), titanium (Ti), vanadium (V), manganese (Mn), cobalt (Co), nickel (Ni), copper (Cu) or zinc (Zn). These metal ions or metals are potentially present from the starting materials/reactor employed to synthesize the precursors. As used herein, the term “substantially free” as it relates to Li, Na, K, Mg, Ca, Al, Fe, Ni, Cr, Ti, V, Mn, Co, Ni, Cu or Zn means less than 5 ppm (by weight), preferably less than 3 ppm, and more preferably less than 1 ppm, and most preferably 0.1 ppm as measured by ICP-MS.

Unless otherwise indicated, “alkyl” refers to a C₁ to C₂₀ hydrocarbon groups which can be linear, branched (e.g., methyl, ethyl, propyl, isopropyl, tert-butyl and the like) or cyclic (e.g., cyclohexyl, cyclopropyl, cyclopentyl and the like). These alkyl moieties may be substituted or unsubstituted as described below. The term “alkyl” refers to such moieties with C₁ to C₂₀ carbons. It is understood that for structural reasons linear alkyls start with C₁, while branched alkyls and cyclic alkyls start with C₃. Moreover, it is further understood that moieties derived from alkyls described below, such as alkyloxy and perfluoroalkyl, have the same carbon number ranges unless otherwise indicated. If the length of the alkyl group is specified as other than described above, the above described definition of alkyl still stands with respect to it encompassing all types of alkyl moieties as described above and that the structural consideration with regards to minimum number of carbons for a given type of alkyl group still apply.

Halo or halide refers to a halogen, F, Cl, Br or I which is linked by one bond to an organic moiety. In some embodiments, the halogen is F. In other embodiments, the halogen is Cl.

Halogenated alkyl refers to a C₁ to C₂₀ alkyl which is fully or partially halogenated.

Perfluoroalkyl refers to a linear, cyclic or branched saturated alkyl group as defined above in which the hydrogens have all been replaced by fluorine (e.g., trifluoromethyl, perfluoroethyl, perfluoropropyl, perfluorobutyl, perfluoroisopropyl, perfluorocyclohexyl and the like).

The disclosed and claimed precursors are preferably substantially free of organic impurities which are from either starting materials employed during synthesis or by-products generated during synthesis. Examples include, but not limited to, alkanes, alkenes, alkynes, dienes, ethers, esters, acetates, amines, ketones, amides, aromatic compounds. As used herein, the term “free of” organic impurities, means 1000 ppm or less as measured by GC, preferably 500 ppm or less (by weight) as measured by GC, most preferably 100 ppm or less (by weight) as measured by GC or other analytical method for assay. Importantly the precursors preferably have purity of 98 wt. % or higher, more preferably 99 wt. % or higher as measured by GC when used as precursor to deposit the ruthenium-containing films.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

As noted above, the disclosed and claimed subject matter relates to ruthenium pyrazolate precursors of Formula I:

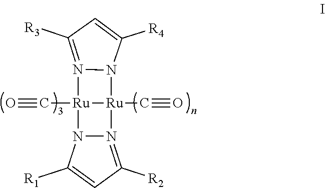

where R₁, R₂, R₃ and R₄ are each independently selected from the group of a substituted or unsubstituted C₁ to C₂₀ linear or branched or cyclic alkyl and a substituted or unsubstituted C₁ to C₂₀ linear or branched or cyclic halogenated alkyl and where n=2 or 3. In another aspect of this embodiment, R₁, R₂, R₃ and R₄ are each independently one of —CH₃, —CH₂CH₃, CH₂CH₂CH₃, CH(CH₃)₂, —CH₂CH(CH₃)₂ and —C(CH₃)₃. The Ru-Pz precursor is a member of the class of compounds covered by Formula I. In another aspect of this embodiment, one or more of R₁ R₂, R₃ and R₄ is sterically bulky group (e.g., t-butyl groups). In another aspect of this embodiment, one or more of R₁ R₂, R₃ and R₄ is each independently one of CF₃, —CF₂CF₃, —CF₂CF₂CF₃, —CF(CF₃)₂, —C(CF₃)₃, and any substituted or unsubstituted C₁ to C₈ perfluorinated alkyl. In another aspect of this embodiment, at least one of R₁, R₂, R₃ and R₄ is a substituted or unsubstituted C₁ to C₈ perfluorinated alkyl. In another aspect of this embodiment, each of R₁ and R₄ are the same group. In another aspect of this embodiment, each of R₂ and R₃ are the same group. In another aspect of this embodiment, each of R₁, R₂, R₃ and R₄ is the same group. In one aspect of this embodiment, n=2. In one aspect of this embodiment, n=3.

In one embodiment, the disclosed and claimed subject matter relates to a ruthenium pyrazolate precursor of Formula I having the following structure:

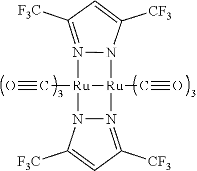

(herein “Ru-Pz 1”) as well as derivatives thereof for use in ALD or ALD-like processes. In a further aspect of this embodiment, the ALD or ALD-like process is applied to grow a film on a substrate including one or more of an oxide substrate or surface such as Al₂O₃, ZrO₂, HfO₂ and SiO₂, a non-oxide such as WCN, WN and TiN, or a metal surface such as Cu, Co, Mo or W. In a further aspect of this embodiment, the ALD or ALD-like process is conducted at a temperature below approximately 300° C. In a further aspect of this embodiment, the ALD or ALD-like process is conducted at a temperature below approximately 275° C. In a further aspect of this embodiment, the ALD or ALD-like process is conducted at a temperature below approximately 250° C. In a further aspect of this embodiment, the ALD or ALD-like process is conducted at a temperature in the range of approximately 200° C. and approximately 300° C. In a further aspect of this embodiment, the ALD or ALD-like process is conducted at a temperature in the range of approximately 235° C. and approximately 300° C.

In another embodiment, the disclosed and claimed subject matter relates to a ruthenium pyrazolate precursor of Formula I having the following structure:

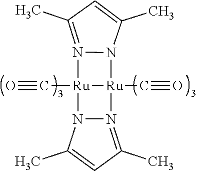

(herein “Ru-Pz 2”) as well as derivatives thereof for use in ALD or ALD-like processes. In a further aspect of this embodiment, the ALD or ALD-like process is applied to grow a film on a substrate including one or more of an oxide substrate or surface such as Al₂O₃, ZrO₂, HfO₂ and SiO₂, a non-oxide such as WCN, WN and TiN, or a metal surface such as Cu, Co, Mo or W. In a further aspect of this embodiment, the ALD or ALD-like process is conducted at a temperature below approximately 300° C. In a further aspect of this embodiment, the ALD or ALD-like process is conducted at a temperature below approximately 275° C. In a further aspect of this embodiment, the ALD or ALD-like process is conducted at a temperature below approximately 250° C. In a further aspect of this embodiment, the ALD or ALD-like process is conducted at a temperature in the range of approximately 200° C. and approximately 300° C. In a further aspect of this embodiment, the ALD or ALD-like process is conducted at a temperature in the range of approximately 235° C. and approximately 300° C.

In another embodiment, the disclosed and claimed subject matter relates to a ruthenium pyrazolate precursor of Formula I having the following structure:

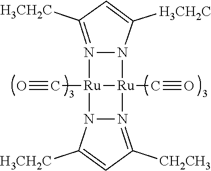

(herein “Ru-Pz 3”) as well as derivatives thereof for use in ALD or ALD-like processes. In a further aspect of this embodiment, the ALD or ALD-like process is applied to grow a film on a substrate including one or more of an oxide substrate or surface such as Al₂O₃, ZrO₂, HfO₂ and SiO₂, a non-oxide such as WCN, WN and TiN, or a metal surface such as Cu, Co, Mo or W. In a further aspect of this embodiment, the ALD or ALD-like process is conducted at a temperature below approximately 300° C. In a further aspect of this embodiment, the ALD or ALD-like process is conducted at a temperature below approximately 275° C. In a further aspect of this embodiment, the ALD or ALD-like process is conducted at a temperature below approximately 250° C. In a further aspect of this embodiment, the ALD or ALD-like process is conducted at a temperature in the range of approximately 200° C. and approximately 300° C. In a further aspect of this embodiment, the ALD or ALD-like process is conducted at a temperature in the range of approximately 235° C. and approximately 300° C.

In another embodiment, the disclosed and claimed subject matter relates to a ruthenium pyrazolate precursor of Formula I having the following structure:

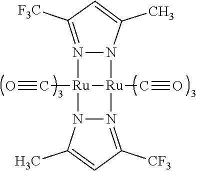

(herein “Ru-Pz 4”) as well as derivatives thereof for use in ALD or ALD-like processes. In a further aspect of this embodiment, the ALD or ALD-like process is applied to grow a film on a substrate including one or more of an oxide substrate or surface such as Al₂O₃, ZrO₂, HfO₂ and SiO₂, a non-oxide such as WCN, WN and TiN, or a metal surface such as Cu, Co, Mo or W. In a further aspect of this embodiment, the ALD process is conducted at a temperature below approximately 300° C. In a further aspect of this embodiment, the ALD or ALD-like process is conducted at a temperature below approximately 275° C. In a further aspect of this embodiment, the ALD or ALD-like process is conducted at a temperature below approximately 250° C. In a further aspect of this embodiment, the ALD or ALD-like process is conducted at a temperature in the range of approximately 200° C. and approximately 300° C. In a further aspect of this embodiment, the ALD or ALD-like process is conducted at a temperature in the range of approximately 235° C. and approximately 300° C.

In another embodiment, the disclosed and claimed subject matter relates to a ruthenium pyrazolate precursor of Formula I having the following structure:

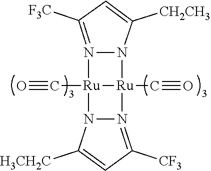

(herein “Ru-Pz 5”) as well as derivatives thereof for use in ALD or ALD-like processes. In a further aspect of this embodiment, the ALD process is applied to grow a film on a substrate including one or more of an oxide substrate or surface such as Al₂O₃, ZrO₂, HfO₂ and SiO₂, a non-oxide such as WCN, WN and TiN, or a metal surface such as Cu, Co, Mo or W. In a further aspect of this embodiment, the ALD or ALD-like process is conducted at a temperature below approximately 300° C. In a further aspect of this embodiment, the ALD or ALD-like process is conducted at a temperature below approximately 275° C. In a further aspect of this embodiment, the ALD or ALD-like process is conducted at a temperature below approximately 250° C. In a further aspect of this embodiment, the ALD or ALD-like process is conducted at a temperature in the range of approximately 200° C. and approximately 300° C. In a further aspect of this embodiment, the ALD or ALD-like process is conducted at a temperature in the range of approximately 235° C. and approximately 300° C.

Examples of ALD or ALD-like growth conditions for the precursors having Formula I, including Ru-Pz 1, Ru-Pz 2, Ru-Pz 3, Ru-Pz 4 and Ru-Pz 5, include, but are not limited to:

a. Substrate temperature: 200-300° C. and ranges therein;

b. Evaporator temperature (metal precursor temperature): 100-130° C.;

c. Reactor pressure: 0.01-20 Torr and ranges therein;

d. Precursor: pulse time: 1-15 sec; purge time 1-20 sec;

e. Reactive gas (co-reactant): pulse time 1-60 sec; purge time 1-90 sec; where the pulse peak pressure of the reactive gas can be substantially higher (e.g., 700 Torr) than the steady state reactor pressure;

g. Pulse sequence (metal complex/purge/reactive gas/purge): pulse and purge times will vary according to chamber size; and

h. Number of cycles: will vary according to desired film thickness.

In one embodiment, the ALD or ALD-like process is conducted at a temperature of approximately 245° C. and includes a co-reactant under the following reaction parameters:

a. Pressure: approximately 10 Torr;

b. Precursor: pulse time: approximately 10 sec; purge time approximately 15 sec; and

c. H₂ co-reactant: pulse time approximately 40 sec; purge time approximately 60 sec.

In a further aspect of this embodiment, the co-reactant is H₂.

In one ALD or ALD-like process embodiment, the ALD or ALD-like process using precursors having Formula I is applied to grow a film on a substrate including one or more of Al₂O₃, ZrO₂, HfO₂ and SiO₂, a non-oxide such as WCN, WN and TiN, or a metal surface such as Cu, Co, Mo or W and combinations thereof. In a further aspect of this embodiment, the disclosed and claimed precursors of Formula I, including Ru-Pz 1, Ru-Pz 2, Ru-Pz 3, Ru-Pz 4 and Ru-Pz 5, are (i) solid at room temperature, (ii) are thermally stable, (iii) have a vapor pressure sufficient to enable evaporation at standard operating temperatures and pressures and/or (iv) can effectively and easily be utilized to deposit oxygen-free Ru films with hydrogen co-reactant with a resistivity of as low as approximately 20 μΩ-cm at approximately 225-295° C. (as-deposited).

In another embodiment, the disclosed and claimed subject matter relates to the use of precursors having Formula I, including Ru-Pz 1, Ru-Pz 2, Ru-Pz 3, Ru-Pz 4 and Ru-Pz 5, where the ALD or ALD-like process is conducted at a pressure between approximately 0.01 and approximately 20 Torr. In a further aspect of this embodiment, the ALD or ALD-like process is conducted at a pressure between approximately 1 and approximately 15 Torr. In a further aspect of this embodiment, the ALD or ALD-like process is conducted at a pressure between approximately 5 and approximately 15 Torr. In a further aspect of this embodiment, the ALD or ALD-like process is conducted at a pressure between approximately 5 and approximately 10 Torr. In a further aspect of this embodiment, the ALD or ALD-like process is conducted at a pressure of approximately 5 Torr. In a further aspect of this embodiment, the ALD or ALD-like process is conducted at a pressure of approximately 10 Torr. In a further aspect of this embodiment, the ALD or ALD-like process is conducted at a pressure of approximately 15 Torr. In a further aspect of this embodiment, the ALD or ALD-like process is conducted at a pressure of approximately 20 Torr. In a further aspect of this embodiment, the ALD or ALD-like process is conducted at any one of the forgoing pressures or pressure ranges in conjunction with at least one oxygen-free co-reactant. In a further aspect of this embodiment, the ALD or ALD-like process is conducted at any one of the forgoing pressures or pressure ranges in conjunction with an H₂ gas co-reactant. In a further aspect of this embodiment, the ALD or ALD-like process is conducted at any one of the forgoing pressures or pressure ranges in conjunction with at least one oxygen-containing co-reactant. In a further aspect of this embodiment, the ALD or ALD-like process is conducted at any one of the forgoing pressures or pressure ranges in conjunction with an O₂ gas co-reactant.

In another embodiment, the disclosed and claimed subject matter relates to the use of precursors having Formula I, including Ru-Pz 1, Ru-Pz 2, Ru-Pz 3, Ru-Pz 4 and Ru-Pz 5, where the ALD or ALD-like process includes the use of at least one oxygen-free co-reactant. In one aspect of this embodiment, the oxygen-free co-reactant includes hydrogen. In one aspect of this embodiment, the oxygen-free co-reactant includes a nitrogen-containing co-reactant. In one aspect of this embodiment, the oxygen-free co-reactant includes a nitrogen-containing co-reactant that is one or more of ammonia, hydrazine, an alkylhydrazine and an alkyl amine. In one aspect of this embodiment, the oxygen-free co-reactant includes ammonia. In one aspect of this embodiment, the oxygen-free co-reactant includes hydrazine. In one aspect of this embodiment, the oxygen-free co-reactant includes an alkylhydrazine. In one aspect of this embodiment, the oxygen-free co-reactant includes an alkyl amine.

In another embodiment, the disclosed and claimed subject matter relates to the use of precursors having Formula I, including Ru-Pz 1, Ru-Pz 2, Ru-Pz 3, Ru-Pz 4 and Ru-Pz 5, where the ALD or ALD-like process includes the use of at least one oxygen-containing co-reactant. In one aspect of this embodiment, the oxygen-containing co-reactant is a reaction gas containing one or more of oxygen (e.g., ozone, elemental oxygen, molecular oxygen/O₂), hydrogen peroxide and nitrous oxide. In one embodiment, O₂ is a preferred co-reactant gas. In one embodiment, ozone is a preferred co-reactant gas.

In another embodiment, the disclosed and claimed subject matter relates to the use of precursors having Formula I, including Ru-Pz 1, Ru-Pz 2, Ru-Pz 3, Ru-Pz 4 and Ru-Pz 5, where the ALD or ALD-like process includes a precursor pulse time of approximately 1 sec to approximately 15 sec. In a further aspect of this embodiment, the precursor pulse time is approximately 1 sec to approximately 10 sec. In a further aspect of this embodiment, the precursor pulse time is approximately 5 sec to approximately 10 sec. In a further aspect of this embodiment, the precursor pulse time is approximately 5 sec. In a further aspect of this embodiment, the precursor pulse time is approximately 10 sec. In a further aspect of this embodiment, the precursor pulse time is approximately 15 sec.

In another embodiment, the disclosed and claimed subject matter relates to the use of precursors having Formula I, including Ru-Pz 1, Ru-Pz 2, Ru-Pz 3, Ru-Pz 4 and Ru-Pz 5, where the ALD or ALD-like process includes a precursor purge time of approximately 1 sec to approximately 20 sec. In a further aspect of this embodiment, the precursor purge time is approximately 1 sec to approximately 15 sec. In a further aspect of this embodiment, the precursor purge time is approximately 5 sec to approximately 15 sec. In a further aspect of this embodiment, the precursor purge time is approximately 10 sec to approximately 15 sec. In a further aspect of this embodiment, the precursor purge time is approximately 10 sec. In a further aspect of this embodiment, the precursor purge time is approximately 15 sec.

In another embodiment, the disclosed and claimed subject matter relates to the use of precursors having Formula I, including Ru-Pz 1, Ru-Pz 2, Ru-Pz 3, Ru-Pz 4 and Ru-Pz 5, where the ALD or ALD-like process includes a co-reactant pulse time of approximately 1 sec to approximately 60 sec. In a further aspect of this embodiment, the co-reactant pulse time is approximately 10 sec to approximately 50 sec. In a further aspect of this embodiment, the co-reactant pulse time is approximately 20 sec to approximately 40 sec. In a further aspect of this embodiment, the co-reactant pulse time is approximately 30 sec to approximately 40 sec. In a further aspect of this embodiment, the co-reactant pulse time is approximately 10 sec. In a further aspect of this embodiment, the co-reactant pulse time is approximately 20 sec. In a further aspect of this embodiment, the co-reactant pulse time is approximately 30 sec. In a further aspect of this embodiment, the co-reactant pulse time is approximately 40 sec. In a further aspect of this embodiment, the co-reactant pulse time is approximately 50 sec. In a further aspect of this embodiment, the co-reactant pulse time is approximately 60 sec. In a further aspect of this embodiment, the ALD or ALD-like process is conducted at any one of the forgoing pressures or pressure ranges in conjunction with an H₂ gas co-reactant. In a further aspect of this embodiment, the ALD or ALD-like process is conducted at any one of the forgoing pressures or pressure ranges in conjunction with at least one oxygen-containing co-reactant. In a further aspect of this embodiment, the ALD or ALD-like process is conducted at any one of the forgoing pressures or pressure ranges in conjunction with an O₂ gas co-reactant.

In another embodiment, the disclosed and claimed subject matter relates to the use of precursors having Formula I, including Ru-Pz 1, Ru-Pz 2, Ru-Pz 3, Ru-Pz 4 and Ru-Pz 5, where the ALD or ALD-like process includes a co-reactant purge time of approximately 1 sec to approximately 90 sec. In a further aspect of this embodiment, the co-reactant purge time is approximately 10 sec to approximately 80 sec. In a further aspect of this embodiment, the co-reactant purge time is approximately 20 sec to approximately 70 sec. In a further aspect of this embodiment, the co-reactant purge time is approximately 30 sec to approximately 60 sec. In a further aspect of this embodiment, the co-reactant purge time is approximately 40 sec to approximately 50 sec. In a further aspect of this embodiment, the co-reactant purge time is approximately 10 sec. In a further aspect of this embodiment, the co-reactant purge time is approximately 20 sec. In a further aspect of this embodiment, the co-reactant purge time is approximately 30 sec. In a further aspect of this embodiment, the co-reactant purge time is approximately 40 sec. In a further aspect of this embodiment, the co-reactant purge time is approximately 50 sec. In a further aspect of this embodiment, the co-reactant purge time is approximately 60 sec. In a further aspect of this embodiment, the co-reactant purge time is approximately 70 sec. In a further aspect of this embodiment, the co-reactant purge time is approximately 80 sec. In a further aspect of this embodiment, the co-reactant purge time is approximately 90 sec. In a further aspect of this embodiment, the ALD or ALD-like process is conducted at any one of the forgoing pressures or pressure ranges in conjunction with an H₂ gas co-reactant. In a further aspect of this embodiment, the ALD or ALD-like process is conducted at any one of the forgoing pressures or pressure ranges in conjunction with at least one oxygen-containing co-reactant. In a further aspect of this embodiment, the ALD or ALD-like process is conducted at any one of the forgoing pressures or pressure ranges in conjunction with an O₂ gas co-reactant.

In another embodiment, the disclosed and claimed subject matter relates to the use of precursors having Formula I, including Ru-Pz 1, Ru-Pz 2, Ru-Pz 3, Ru-Pz 4 and Ru-Pz 5, where the ALD or ALD-like process includes a substrate including one or more of Al₂O₃, ZrO₂, HfO₂ and SiO₂, a non-oxide such as WCN, WN and TiN, or a metal surface such as Cu, Co, Mo or W.

In another aspect the disclosed and claimed subject matter relates to films grown from precursors having Formula I, including Ru-Pz 1, Ru-Pz 2, Ru-Pz 3, Ru-Pz 4 and Ru-Pz 5. In a further aspect of this embodiment, the films are grown on a substrate including one or more of Al₂O₃, ZrO₂, HfO₂ and SiO₂, a non-oxide such as WCN, WN and TiN, or a metal surface such as Cu, Co, Mo or W.

TGA/DSC

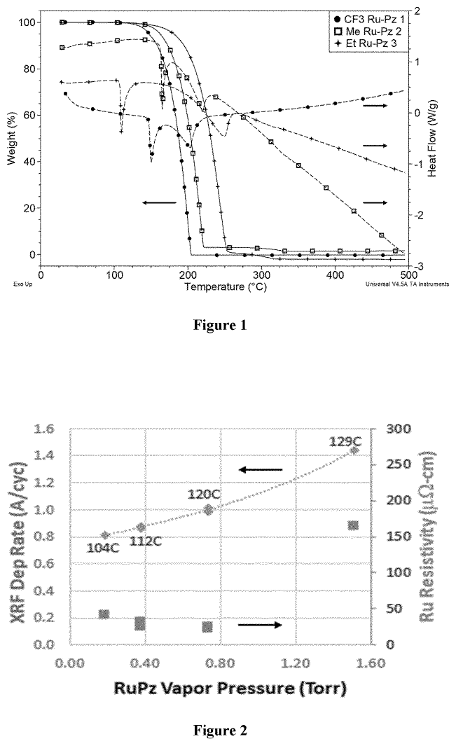

A TGA/DSC analysis of the Ru-Pz 1 precursor was performed with an N₂ carrier gas at 100° C. (measured by TC on ampoule). As illustrated in FIG. 1, the TGA/DSC analysis of the Ru-Pz 1, Ru-Pz 2, or Ru-Pz 3 precursors demonstrates that the precursor evaporates at moderate temperatures and leaves no residue when it is evaporated (i.e., there is no evidence of decomposition). In addition, the DSC data shows that the Ru-Pz 1 precursor has a melting point of approximately 147° C.

Saturation Behavior

Ru deposition rate increased with Ru-Pz 1 vapor pressure as shown in FIG. 2. The vapor pressure was varied by changing the bubbler temperature between 104° C. and 129° C. One ALD cycle consists of a Ru-Pz 1 pulse time of 10 s and argon purge time of 15 s, flowed by a H₂ pulse time of 40 s and argon purge time of 60 s. The deposition pressure was 10 Torr and deposition temperature was 245° C. Resistivity of about 20μΩ·cm was achieved on SiO₂ but increased at a high Ru-Pz 1 vapor pressure of 1.5 Torr or bubbler temperature at 129° C.

Effect of Deposition Pressure

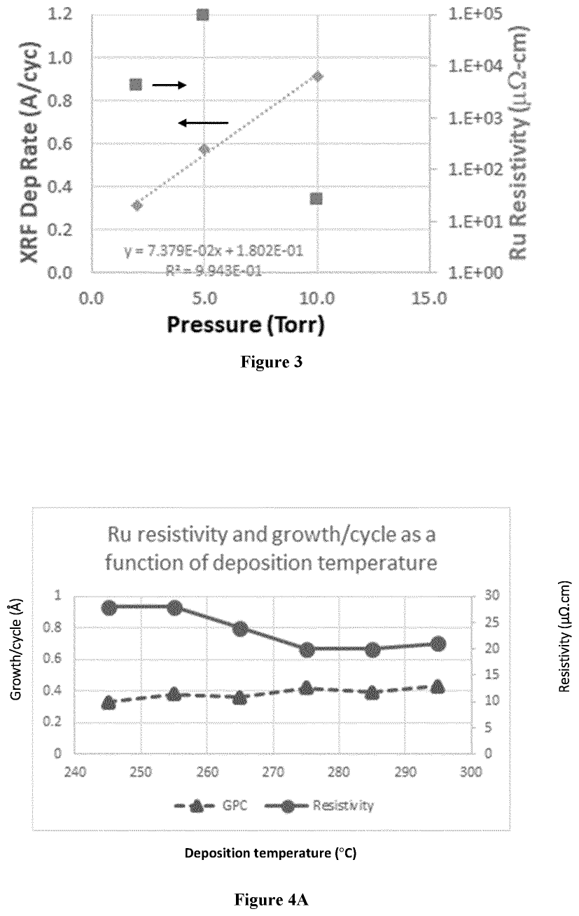

Ru deposition rate increased with deposition pressure and resistivity can also be affected by the deposition pressure as shown in FIG. 3. The deposition temperature was 245° C.

Process Window on SiO₂

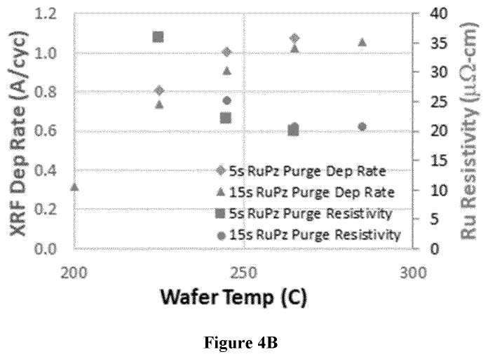

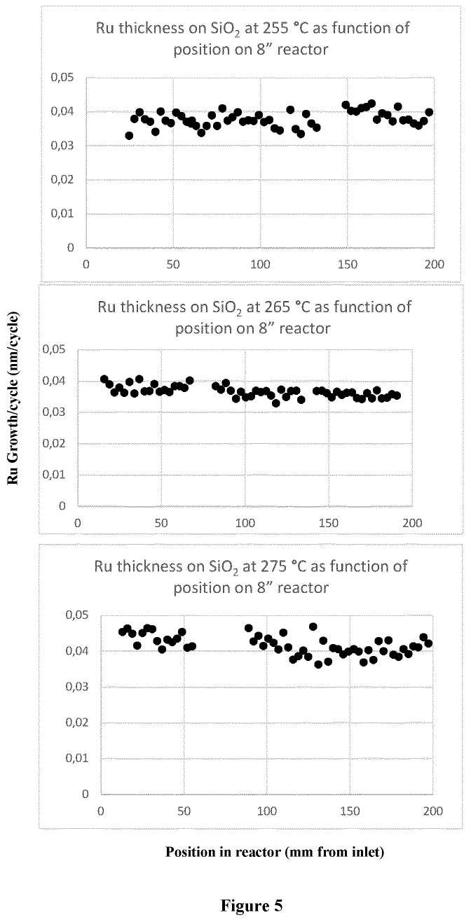

Conductive Ru films grown from the Ru-Pz 1 precursor have been deposited from approximately 200° C. to approximately 295° C. One deposition process included (i) 0.5-second Ru-Pz 1 precursor pulses and a purge of variable length followed by (ii) 3 successive 0.02-second H₂ pulses (separated by 5 seconds) and a purge at a deposition pressure of 1 Torr or lower. The Ru growth/cycle was 0.3-0.4 Angstroms per cycle. As can be seen in FIG. 4A, the Ru films grown from the Ru-Pz 1 precursor had resistivities as low as 20μΩ·cm (as-deposited) when deposited at between approximately 245° C. and approximately 295° C.

Another deposition process using a higher deposition pressure of 10 Torr and a longer 40 s H₂ pulse and 60 s purge, and a 5 s pulse of Ru-Pz 1 and 15 s purge, the process window can be further expanded down to about 200° C. and the growth rate increased up to approximately 1 Angstroms per cycle as shown in FIG. 4B.

Homogeneity of Ru Films

As shown in FIG. 5, Ru films grown from the Ru-Pz 1 precursor demonstrate a very high degree of homogeneity. In FIG. 5, the Ru-Pz 1 precursor was deposited over the 8-inch reactor at 255° C., 265° C. and 275° C., respectively, with 0.02-second purges between the Ru-Pz 1 precursor pulses and the H₂ pulses. Regardless of temperature, the deposited film showed consistent homogeneity.

Thickness

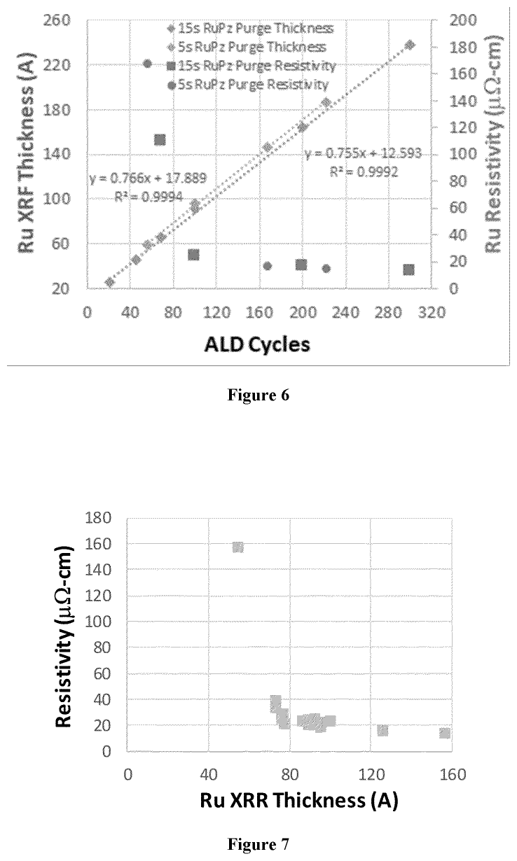

As shown in FIG. 6, Ru films grown from the Ru-Pz 1 precursor and H₂ at 245° C. showed linear thickness with the number of cycles. FIG. 7 illustrates a drop in the resistivity as a function of film thickness down to approximately 20μΩ·cm at approximately 80 Angstroms Ru thickness.

Purge Length

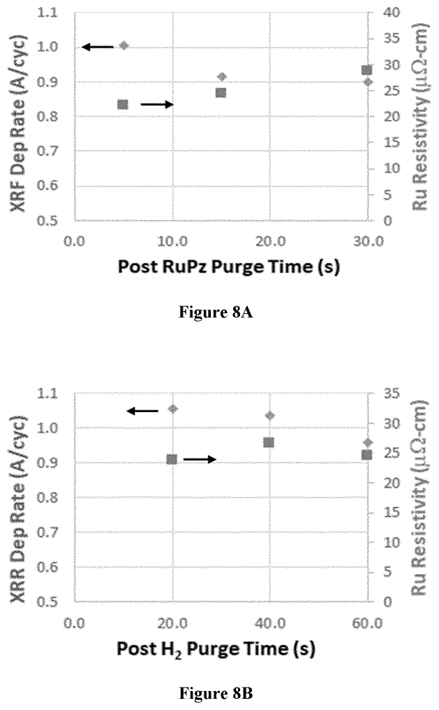

Purge length may have an effect of film growth when using the Ru-Pz 1 precursor. As shown in FIG. 8, film growth using the Ru-Pz 1 precursor at 255° C. using a longer purge time does not negatively impact the Ru-Pz process. On the other hand, a longer purge time at 275° C. results in lower growth and higher resistivity. This phenomenon should allow the deposition of conformal Ru films at 255° C. using the Ru-Pz 1 precursor.

XPS Thick Film

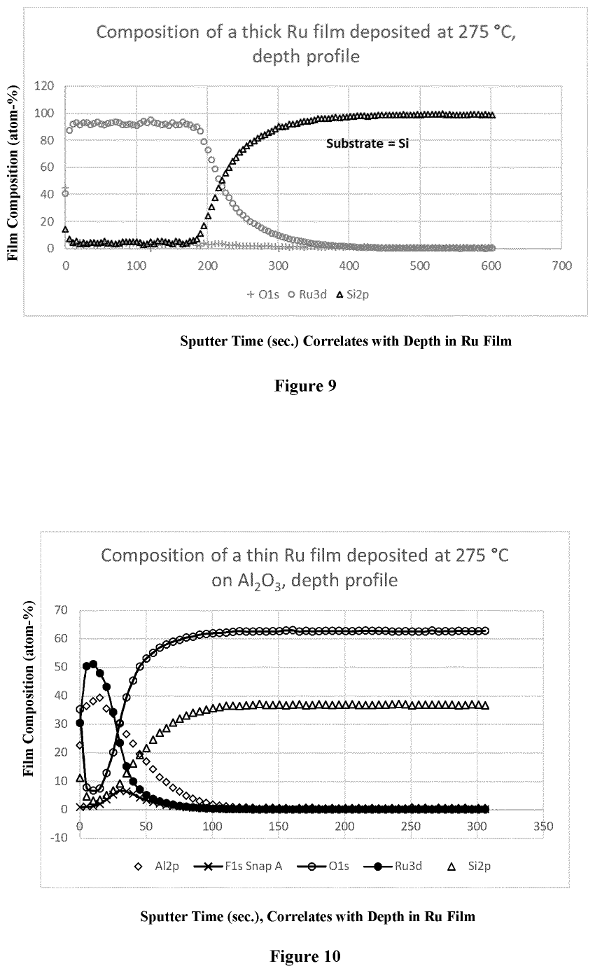

As shown in FIG. 9, an XPS analysis of a 37-nm thick Ru film grown at 275° C. from the Ru-Pz 1 precursor on native SiO₂ showed Ru=93%; Si=4% and 0=3% (N and F are not detectable).

XPS Thin Film

As shown in FIG. 10, an XPS analysis of a thin a film grown from the Ru-Pz 1 precursor on Al₂O₃ shows there is a fluorine-containing layer between the ruthenium and aluminum oxide layers when the Ru is deposited at 275° C.

Film Morphology

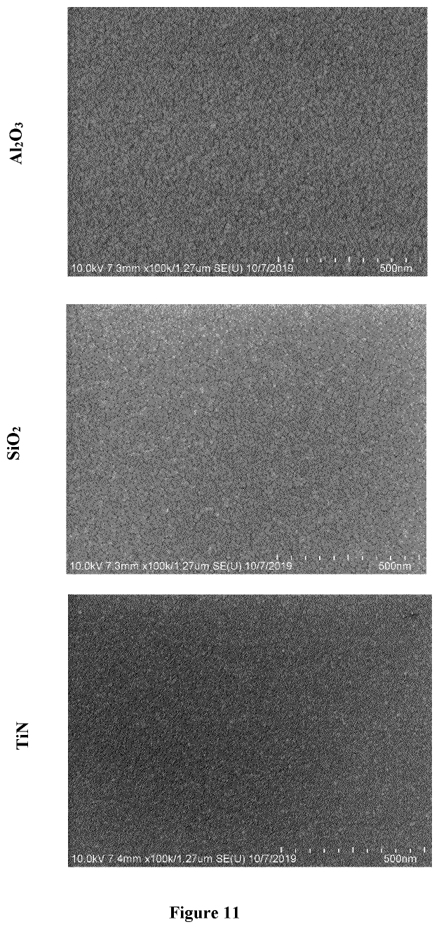

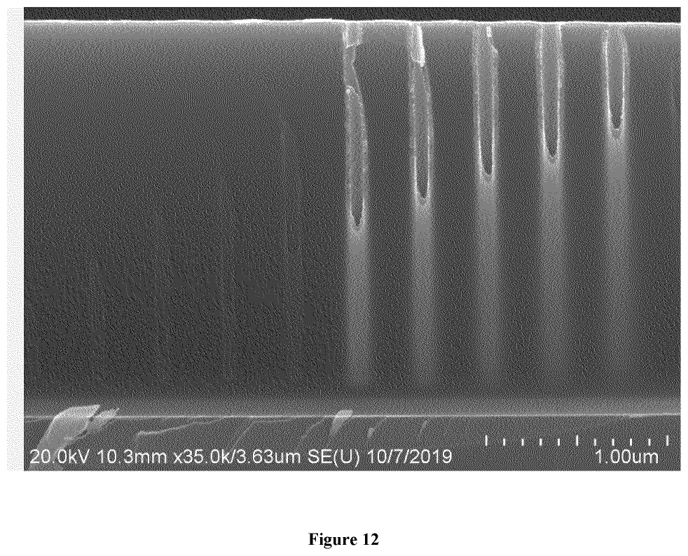

As shown in FIG. 11, Ru film grown from the Ru-Pz 1 precursor is smoother on TiN liner compared to oxides and that the Ru film is smoother on SiO₂ compared to Al₂O₃. Films grown at 275° C. (200 cycles) on different substrates exhibit different degrees of roughness: (i) on Al₂O₃ the Ru film is approximately 8 nm thick and has a RMS (average of 3 measurements) of 0.85 nm (this roughness corresponds to 10.6% of the film's thickness), (ii) on SiO₂ the Ru film is approximately 9 nm thick and has a RMS (average of 3 measurements) of 0.57 nm (this roughness corresponds to 6.3% of the film's thickness), and (iii) on TiN the Ru film is approximately 8 nm thick and has a RMS (average of 3 measurements) of 0.46 nm (this roughness corresponds to 5.7% of the film's thickness).

Conformality

FIG. 10 illustrates the early conformality of an Ru film grown (400 cycles of alternating Ru-Pz and H₂ at 275° C.) from the Ru-Pz 1 precursor on vias (20:1 aspect ratio); the magnification of FIG. 12 is 35,000. As can be seen in FIG. 10, ruthenium is deposited in deep vias having a width of 90 nm and a depth of 1800 nm, the ruthenium spans from the via tops to the via bottoms.

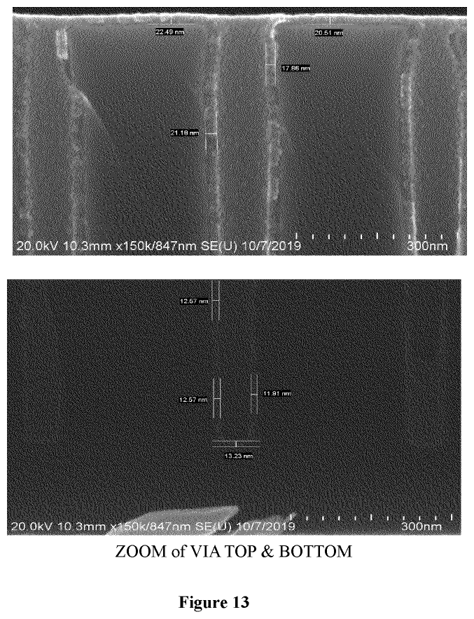

FIG. 13 shows higher magnification micrographs (magnification of 150,000) of the via top and via bottom shown in FIG. 12 and illustrates that the Ru of the film produced in FIG. 12 is 18-21 nm thick at the top of the vias, 12-13 nm thick at the bottom of the vias and has a conformality of approximately 60%. The conformality has been further improved to over 95% at a lower deposition temperature of 245° C.

Crossflow Deposition (Without H₂)

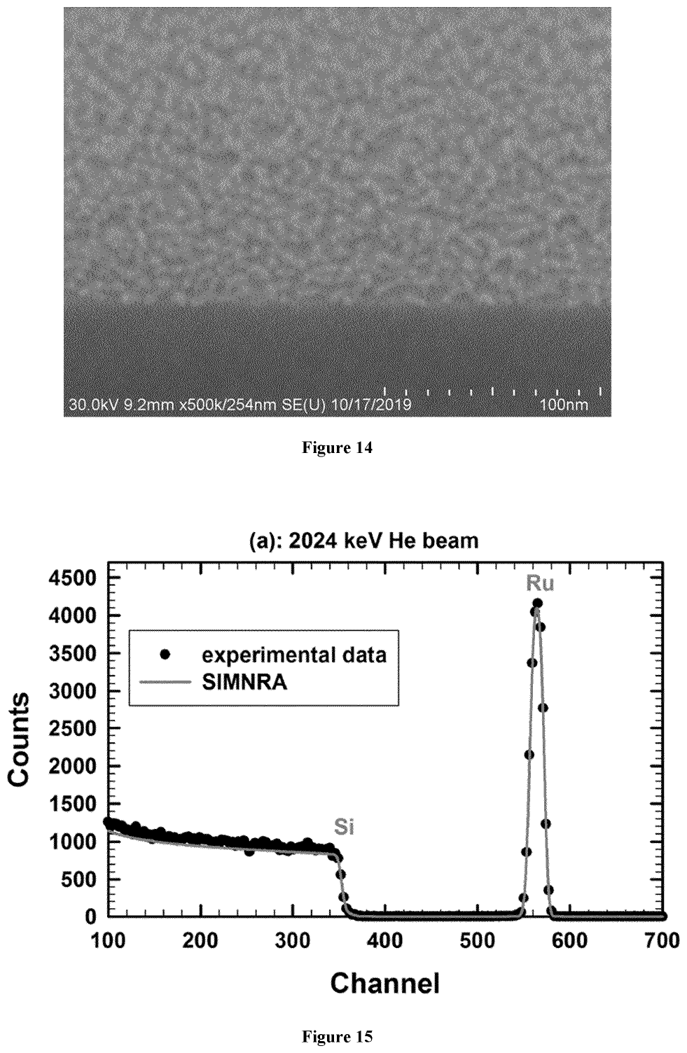

FIG. 14 illustrates the deposition of a Ru film grown on SiO₂ from the Ru-Pz 1 precursor in the absence of H₂ (275° C.) in a crossflow reactor. In particular, FIG. 14 illustrates the growth of an approximately 1-2 nm thick Ru film that was deposited by 400 cycles of Ru-Pz 1 precursor in the absence of hydrogen at 275° C. Compared with 16 nm of Ru when hydrogen is used in 400 comparable cycles at 275° C., the amount of ruthenium deposited at 275° C. in the absence of hydrogen due to thermal decomposition corresponds to approx. 10% of what would be deposited with hydrogen using a comparable process. This result demonstrates that the Ru-Pz 1 precursor is thermally sufficiently stable at 275° C., and the Ru deposition process described herein using H₂ at 275° C. or lower is predominantly an ALD process instead of a thermal CVD process.

XPS (Without H₂)

As shown in Table 1 (below), in the absence of hydrogen no significant deposition of Ru occurs on any substrate at 255-275° C. The XPS data indicates there is a small amount of fluorine on the surface due to thermal decomposition of the Ru-Pz 1 precursor, confirming that Ru-Pz 1 precursor can transfer fluorine atoms to the substrate (at least on SiO₂ substrates). The transfer and presence of fluorine may be beneficial in some applications whereas the precursors and/or process may be further adjusted to reduce, minimize or eliminate the presence of fluorine in the presence of hydrogen.

TABLE 1

| | | | Substrate and process deposition temperature | | | | | | | |
|---|---|---|---|---|---|---|---|---|---|---|
| | | | Al₂O₃ | Al₂O₃ | SiO₂ | SiO₂ | WCN | WCN | TiN | TiN |
| | | | 255° C. | 275° C. | 255° C. | 275° C. | 255° C. | 275° C. | 255° C. | 275° C. |
| Surface | F | (%) | 10.5 | 7.6 | 3.5 | 2.6 | 7.9 | 6.7 | 7.2 | 5.3 |
| compo- | Ru | (%) | 1 | 1.4 | 1.4 | 1.7 | 5.3 | 4.6 | 2.8 | 3 |
| sition | O | (%) | 54 | 55 | 63 | 64 | 58 | 58 | 40 | 41 |
| (XPS) | N | (%) | 2 | 2 | 1.5 | 1.5 | 8.1 | 7.5 | 20 | 20 |
| | Si | (%) | 10 | 11 | 31 | 31 | 4.6 | 6 | 5.6 | 5.8 |
| | Ti | (%) | | | | | | | 24 | 25 |
| | W | (%) | | | | | 16 | 17 | | |
| | Al | (%) | 23 | 23 | | | | | | |

RBS Analysis of Thick Film

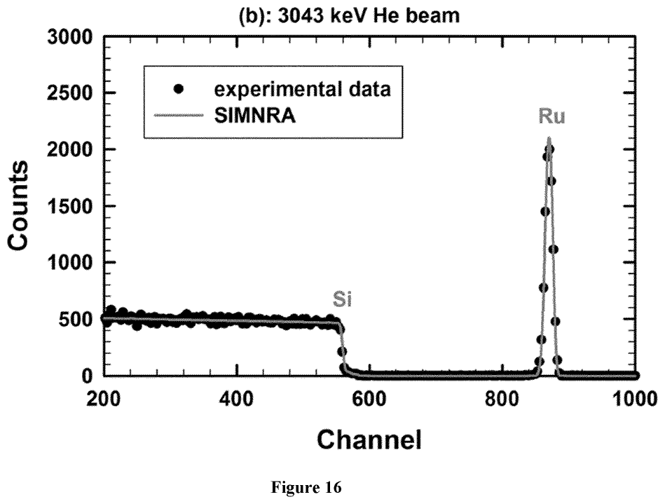

As shown in FIG. 15, the RBS data shows that at 2.024 MeV only Ru and Si elements can be quantified above the detection limit. In FIG. 15, filled symbols are collected data and solid lines are fits to RBS spectra with SIMNRA software.

In FIG. 16, the RBS data shows that at 3.043 MeV only Ru and Si elements can be quantified above the detection limit. In FIG. 14, filled symbols are collected data and solid lines are fits to RBS spectra with SIMNRA software.

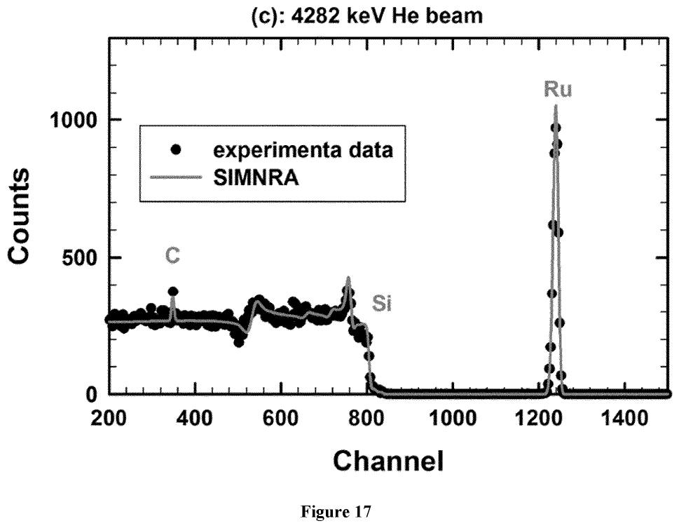

As seen in FIG. 17, the RBS data shows that at 4.282 MeV only Ru and Si elements can be quantified above the detection limit. In FIG. 17 filled symbols are collected data and solid lines are fits to RBS spectra with SIMNRA software. The small signal visible in the simulation containing 0% carbon is due to 22 monolayers of “C_{0.5}H_{0.5}” present on the surface due to contamination by ambient air.

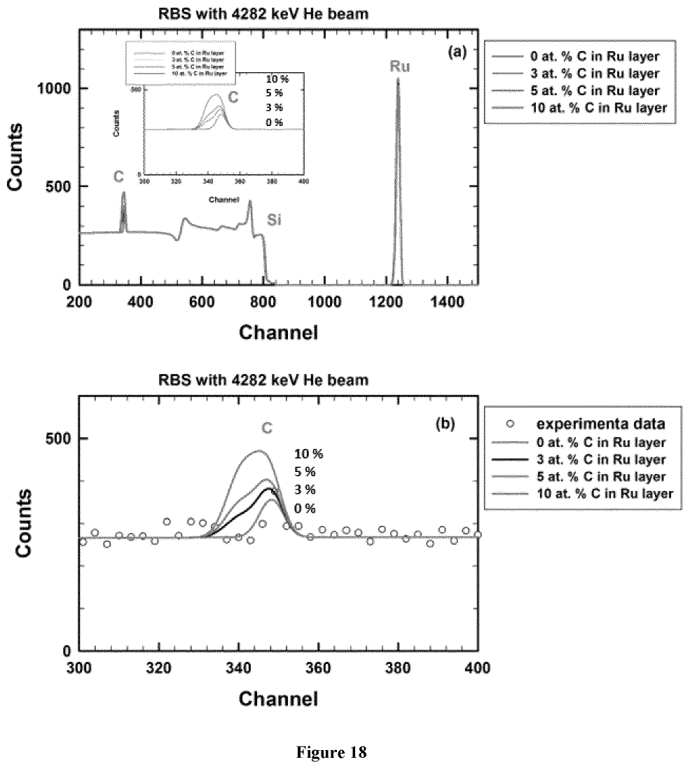

In FIG. 18, the RBS data shows that carbon is non-detectable in a Ru film grown from the Ru-Pz precursor with H₂ (275° C.) in a crossflow reactor. This plot shows the experimental data (circles) and simulations of data showing a ruthenium film containing 0% carbon (red line), a ruthenium film containing 3% carbon (black line), a ruthenium film containing 5% carbon (green line), a ruthenium film containing 10% carbon (blue line). Given the noise of the data, it can be stated the carbon content is below a detection limit of 5%. The small signal visible in the simulation containing 0% carbon is due to 22 monolayers of “C_{0.5}H_{0.5}” present on the surface due to contamination by ambient air.

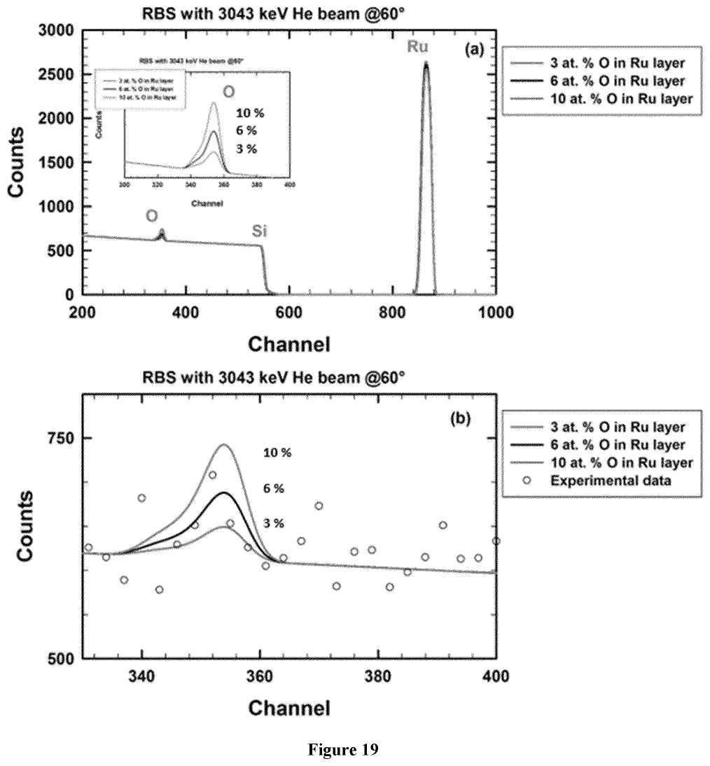

As shown in FIG. 19, the RBS data shows that oxygen is non-detectable in a Ru film grown from the Ru-Pz 1 precursor with H₂ (275° C.) in a crossflow reactor. This plot shows the experimental data (circles) and simulations of data showing a ruthenium film containing 3% oxygen (green line), a ruthenium film containing 6% oxygen (black line), a ruthenium film containing 10% oxygen (red line). Given the noise of the data, it can be stated the oxygen content is below a detection limit of 6%.

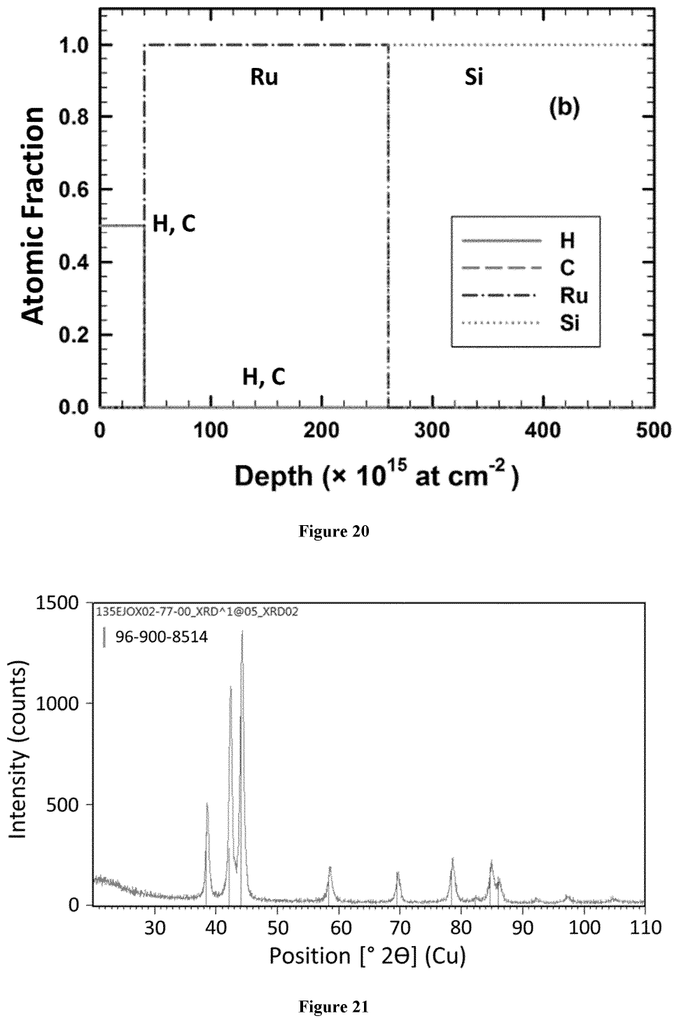

FIG. 20 concludes the RBS analysis and demonstrates that the Ru film grown from the Ru-Pz 1 precursor has 255 monolayers of Ru on the Si and further includes a topping of 22 monolayers of “C_{0.5}H_{0.5}” due to surface contamination by ambient air. These results are summarized in Table 2 (below). A monolayer corresponds to 10¹⁵ at·cm⁻².

TABLE 2

| | | | Thickness |
|---|---|---|---|
| Position | Layer no. | Stoichiometry | (×10¹⁵ at cm⁻²) |
| Possible surface | 1 | C_{0.5}H_{0.5} | 22 |
| contamination | | | |
| Film | 2 | Ru | 255 |
| Substrate | 3 | Si | 100000000 |

FIG. 21 illustrates an XRD pattern of Ru film deposited on Si at 245° C. showing formation of crystalline Ru.

Summary

The Ru-Pz 1 precursor can be effectively used to grow Ru films exhibiting numerous desirable qualities. These beneficial qualities include, but are not limited to: (i) the ability to used effectively with H₂ from 200° C. to more than 300° C.; (ii) good homogeneity in a 8-inch cross-flow reactor, (iii) consistent resistivity of as-deposited films as low as 20μΩ·cm for film thicknesses higher than 8 nm, (iv) low carbon and oxygen contaminations with no fluorine in film (as measured by XPS) and (v) good conformality demonstrated in 20:1 aspect ratio vias at 245-275° C.

Although the invention has been described and illustrated with a certain degree of particularity, it is understood that the disclosure has been made only by way of example, and that numerous changes in the conditions and order of steps can be resorted to by those skilled in the art without departing from the spirit and scope of the invention.

What is claimed is:

1. An ALD or ALD-like precursor comprising ruthenium, represented by Formula I: 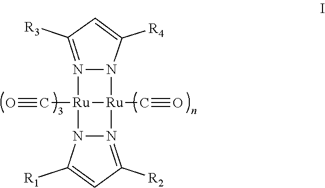
wherein
R₁, R₂, R₃ and R₄ are each independently selected from the group of a substituted or unsubstituted C₁ to C₂₀ linear or branched or cyclic alkyl and a substituted or unsubstituted C₁ to C₂₀ linear or branched or cyclic halogenated alkyl;
n=2 or 3; and
the precursor is preferably substantially free of water, metal ions or metals, and organic impurities.

2. The precursor of claim 1, wherein R₁, R₂, R₃ and R₄ are each independently one of —CH₃, —CH₂CH₃, —CH₂CH₂CH₃, —CH(CH₃)₂, —CH₂CH(CH₃)₂, —C(CH₃)₃, —CF₃, —CF₂CF₃, —CF₂CF₂CF₃, —CF(CF₃)₂, —C(CF₃)₃.

3. The precursor of claim 1, wherein at least one of R₁, R₂, R₃ and R₄ is a substituted or unsubstituted C₁ to C₈ perfluorinated alkyl.

4. The precursor of claim 1, wherein n=2.

5. The precursor of claim 1, wherein n=3.

6. The precursor of claim 1, wherein each of R₁, R₂, R₃ and R₄ is the same group.

7. The precursor of claim 1, wherein each of R₁ and R₄ or R₂ and R₃ are the same group.

8. The precursor of claim 1, having the structure:

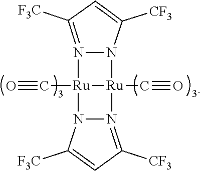

9. The precursor of claim 1, having the structure:

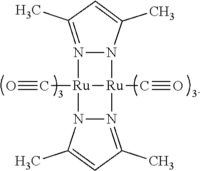

10. The precursor of claim 1, having the structure:

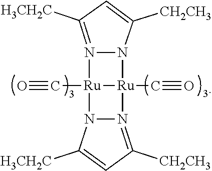

11. The precursor of claim 1, having the structure:

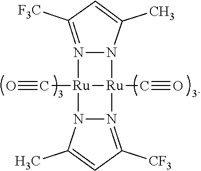

12. The precursor of claim 1, having the structure:

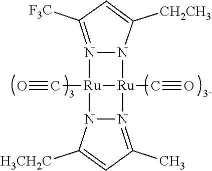

13. An ALD or ALD-like process comprising the step of depositing a ruthenium-containing layer derived from a precursor of any of claims 1 to 12 on a surface of a substrate.

14. The process of claim 13, wherein the surface comprises at least one of Al₂O₃, ZrO₂, HfO₂, SiO₂, WN, WCN, TiN, Cu, Co, Mo, W and combinations thereof.

15. The process of claim 13, wherein the ALD or ALD-like process is conducted at a temperature below approximately 300° C.

16. The process of claim 13, wherein the ALD or ALD-like process is conducted at a temperature below approximately 275° C.

17. The process of claim 13, wherein the ALD or ALD-like process is conducted at a temperature below approximately 250° C.

18. The process of claim 13, wherein the ALD or ALD-like process is conducted at a temperature in the range of approximately 200° C. and approximately 300° C.

19. The process of claim 13, wherein the ALD or ALD-like process is conducted at a temperature in the range of approximately 235° C. and approximately 300° C.

20. The process of claim 13, further comprising the use of a co-reactant.

21. The process of claim 13, further comprising the use of an oxygen-free co-reactant.

22. The process of claim 13, further comprising the use of an oxygen-containing co-reactant.

23. The process of claim 13, further comprising the use of H₂ as a co-reactant.

24. The process of claim 13, further comprising the use of O₂ as a co-reactant.

25. The process of claim 13, wherein the ALD or ALD-like process is conducted at a pressure between approximately 0.01 and approximately 20 Torr.

26. The process of claim 13, wherein the ALD or ALD-like process is conducted at a pressure between approximately 1 and approximately 15 Torr.

27. The process of claim 13, wherein the ALD or ALD-like process is conducted at a pressure between approximately 5 and approximately 15 Torr.

28. The process of claim 13, wherein the ALD or ALD-like process is conducted at a pressure between approximately 5 and approximately 10 Torr.

29. The process of claim 13, wherein the ALD or ALD-like process is conducted at a pressure of approximately 5 Torr.

30. The process of claim 13, wherein the ALD or ALD-like process is conducted at a pressure of approximately 10 Torr.

31. The process of claim 13, wherein the ALD or ALD-like process is conducted at a pressure of approximately 15 Torr.

32. The process of claim 13, wherein the ALD or ALD-like process is conducted with a precursor pulse time of approximately 1 sec to approximately 15 sec.

33. The process of claim 13, wherein the ALD or ALD-like process is conducted with a precursor pulse time of approximately 5 sec to approximately 10 sec.

34. The process of claim 13, wherein the ALD or ALD-like process is conducted with a precursor pulse time of approximately 10 sec.

35. The process of claim 13, wherein the ALD or ALD-like process is conducted with a precursor pulse time of approximately 15 sec.

36. The process of claim 13, wherein the ALD or ALD-like process is conducted with a precursor purge time of approximately 1 sec to approximately 20 sec.

37. The process of claim 13, wherein the ALD or ALD-like process is conducted with a precursor purge time of approximately 5 sec to approximately 15 sec.

38. The process of claim 13, wherein the ALD or ALD-like process is conducted with a precursor purge time of approximately 10 sec. to approximately 15 sec.

39. The process of claim 13, wherein the ALD or ALD-like process is conducted with a precursor purge time of approximately 10 sec.

40. The process of claim 13, wherein the ALD or ALD-like process is conducted with a precursor purge time of approximately 15 sec.

41. The process of claim 13, wherein the ALD or ALD-like process is conducted with a co-reactant pulse time of approximately 1 sec to approximately 60 sec.

42. The process of claim 13, wherein the ALD or ALD-like process is conducted with a co-reactant pulse time of approximately 10 sec to approximately 50 sec.

43. The process of claim 13, wherein the ALD or ALD-like process is conducted with a co-reactant pulse time of approximately 20 sec to approximately 40 sec.

44. The process of claim 13, wherein the ALD or ALD-like process is conducted with a co-reactant pulse time of approximately 30 sec to approximately 40 sec.

45. The process of claim 13, wherein the ALD or ALD-like process is conducted with a co-reactant pulse time of approximately 30 sec.

46. The process of claim 13, wherein the ALD or ALD-like process is conducted with a co-reactant pulse time of approximately 40 sec.

47. The process of claim 13, wherein the ALD or ALD-like process is conducted with a co-reactant pulse time of approximately 50 sec.

48. The process of claim 13, wherein the ALD or ALD-like process is conducted with a co-reactant purge time of approximately 1 sec to approximately 90 sec.

49. The process of claim 13, wherein the ALD or ALD-like process is conducted with a co-reactant purge time of approximately 10 sec to approximately 80 sec.

50. The process of claim 13, wherein the ALD or ALD-like process is conducted with a co-reactant purge time of approximately 20 sec to approximately 70 sec.

51. The process of claim 13, wherein the ALD or ALD-like process is conducted with a co-reactant purge time of approximately 30 sec to approximately 60 sec.

52. The process of claim 13, wherein the ALD or ALD-like process is conducted with a co-reactant purge time of approximately 50 sec.

53. The process of claim 13, wherein the ALD or ALD-like process is conducted with a co-reactant purge time of approximately 60 sec.

54. The process of claim 13, wherein the ALD or ALD-like process is conducted with a co-reactant purge time of approximately 70 sec.

55. An ALD or ALD-like-deposited film comprising the reaction product of a precursor of any of claims 1 to 12 and at least one oxygen-free co-reactant.

56. The ALD- or ALD-like deposited film of claim 55, wherein the oxygen-free co-reactant comprises hydrogen.

57. The ALD- or ALD-like deposited film of claim 55, wherein the oxygen-free co-reactant comprises a nitrogen-containing co-reactant.

58. The ALD- or ALD-like deposited film of claim 55, wherein the oxygen-free co-reactant comprises one or more of ammonia, hydrazine, an alkylhydrazine and an alkyl amine.

59. An ALD- or ALD-like deposited film comprising the reaction product of a precursor of any of claims 1 to 12 and at least one oxygen-containing co-reactant.

60. The ALD- or ALD-like deposited film of claim 59, wherein the oxygen-containing co-reactant comprises one or more of oxygen, hydrogen peroxide and nitrous oxide.

61. The ALD- or ALD-like deposited film of claim 59, wherein the oxygen-containing co-reactant comprises one or more of ozone, elemental oxygen and molecular oxygen/O₂.

62. The ALD- or ALD-like deposited film of claim 59, wherein the oxygen-containing co-reactant comprises O₂.

63. The process of claim 13, wherein the ALD or ALD-like process is conducted:
(i) at a temperature of approximately 245° C.;
(ii) at a pressure of approximately 10 Torr;
(iii) with a precursor pulse time of approximately 10 sec;
(iv) with a precursor purge time of approximately 15 sec;
(v) with a co-reactant pulse time of approximately 40 sec; and
(vi) with a co-reactant purge time of approximately 60 sec.

64. The process of claim 63, wherein the co-reactant is H₂.

65. The use of the precursor of any one of claims 1 to 12 in ALD and ALD-like processes.
